(19) United States
(12) Patent Application Publication
(10) Pub. No.: US 2026/0269570 A1
(43) Pub. Date: Sep. 10, 2026

(54) METASURFACE ENABLED COMPACT CHIRAL-VERTICAL CAVITY SURFACE EMITTING LASER

(71) Applicant: ams-OSRAM International GmbH, Regensburg (DE)

(72) Inventors: Aimi ABASS, Regensburg (DE); Rasoul ALAEE KHANGHAH, Obertraubling (DE)

(21) Appl. No.: 19/489,273

(22) PCT Filed: Jul. 30, 2024
(86) PCT No.: PCT/EP2024/071550

§ 371 Date: Dec. 2, 2025

(30) Foreign Application Priority Data
Sep. 6, 2023 (DE) 10 2023 123 971.6

(51) Int. Cl. H01S 5/183; H01S 5/125

(52) U.S. Cl. CPC H01S 5/18355; H01S 5/125; H01S 5/18369

(57) ABSTRACT

Vertical cavity surface emitting laser component are provided, including a light emitting structure configured to emit a light of a frequency, and at least one mirror structure on or above the light emitting structure, wherein the mirror structure comprises a plurality of optical nano-elements, wherein the optical nano-elements are configured to comprise a first reflectivity for light of the frequency having a first chirality and a second reflectivity for light of the frequency having a second chirality, wherein the second chirality is opposing to the first chirality, and wherein the first reflectivity is larger than the second reflectivity.

### CROSS-REFERENCE TO RELATED APPLICATIONS

This is a national phase of international application PCT/EP2024/071550, which was filed on Jul. 30, 2024, the entire contents of which are incorporated herein by reference.

### TECHNICAL FIELD

This disclosure generally relates to vertical cavity surface emitting laser (VCSEL) components and chiral light sources.

### BACKGROUND

Chiral coherent light is frequently used in medical, biosensing and other applications. However, known chiral coherent light sources are often bulky as it requires large additional external optical components and are difficult to miniaturize.

In VCSELs, Distributed Bragg Reflectors (DBR) on both sides of the VCSEL component create a resonant cavity in the VCSEL component and achieve lasing. However, due to a fairly broadband response of typical DBR mirrors, there are difficulties in maintaining a single mode operation especially when the aperture is large. Multimode operation of a VCSEL results in energy inefficiency and a more complicated wave-front to deal with.

### BRIEF SUMMARY

In one aspect, a vertical cavity surface emitting laser, VCSEL, component, includes a light emitting structure configured to emit a light of a frequency, and at least one mirror structure on or above the light emitting structure, wherein the mirror structure comprises a plurality of optical nano-elements, wherein the optical nano-elements are configured to comprise a first reflectivity for light of the frequency having a first chirality and a second reflectivity for light of the frequency having a second chirality, wherein the second chirality is opposing to the first chirality, and wherein the first reflectivity is larger than the second reflectivity.

In the VCSEL component chiral one or more metasurfaces formed by the plurality of optical nano-elements may act as a mirror with high quality factor (also denoted as Q-factor) and thus allowing mode selection, and may offer extreme circular dichroism-e.g. reflecting only light of purely left or right circular polarization. Thus, the VCSEL component allows adjusting chirality of the emitted laser output light, e.g. without utilizing bulky liquid crystal or other external optical components.

Illustratively, the VCSEL component can be inherently chiral at the chip level, and thus can have a very compact design, e.g. can have an improved integrability. The VCSEL component may provide single mode operation for larger aperture sizes.

In other words, the VCSEL component may include at least one chiral metasurface that is a highly efficient reflector with no parasitic absorption. Thus, the metasurface can replace the top/front side DBR mirror of a comparative VCSEL component at the design wavelength. The metasurface can be highly wavelength selective due to the high Q factor of the resonance that is exploited and also highly selective of light chirality (e.g., zero reflection for left-handed circular polarization and near 100% reflection for the right-handed circular polarization).

In another aspect, a method to manufacture a vertical cavity surface emitting laser, VCSEL, component, includes forming a light emitting structure configured to emit a light of a frequency, and forming at least one mirror structure on or above the light emitting structure, wherein the mirror structure is formed comprising a plurality of optical nano-elements, wherein the optical nano-elements are configured to comprise a first reflectivity for light of the frequency having a first chirality and a second reflectivity for light of the frequency having a second chirality, wherein the second chirality is opposing to the first chirality, and wherein the first reflectivity is larger than the second reflectivity.

The provided VCSEL component is scalable and suitable for mass production.

### BRIEF SUMMARY OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A shows a schematic cross-sectional side view of a chiral mirror structure of a VCSEL component;

FIG. 1B shows a schematic cross-sectional top view of a chiral mirror structure of a VCSEL component;

FIG. 2 shows a schematic cross-sectional side view of a VCSEL component;

FIG. 3A-3C show schematic cross-sectional side views of VCSEL components;

FIG. 4A-4D show illustration of details of a chiral mirror structure of a VCSEL component;

FIG. 5A-5B show illustration of details of a chiral mirror structure of a VCSEL component; and

FIG. 6 is a flow diagram of a method to manufacture a VCESL component.

### DETAILED DESCRIPTION

The following detailed description refers to the accompanying drawings that show, by way of illustration, specific details and aspects in which the disclosure may be practiced. One or more aspects are described in sufficient detail to enable those skilled in the art to practice the disclosure. Other aspects may be utilized and structural, logical, and electrical changes may be made without departing from the scope of the disclosure. The various aspects described herein are not necessarily mutually exclusive, as some aspects can be combined with one or more other aspects to form new aspects. Various aspects are described in connection with methods and various aspects are described in connection with devices. However, it may be understood that aspects described in connection with methods may similarly apply to the devices, and vice versa. Throughout the drawings, it should be noted that like reference numbers are used to depict the same or similar elements, features, and structures. Throughout the drawings, it should be noted that proportions are not necessary to scale and that the size of features may be emphasized for ease of illustration.

Illustratively, a VCSEL component having a metasurface as a reflector of the optical cavity of the VCSEL is provided. The metasurface is configured to supports a Mie-type resonance referred to as chiral “Quasi Bound state In the Continuum”, also denoted as quasi-BIC, as discussed in detail in OVERVIG. Thus, the metasurface reflector may thus also be denoted as quasi-BIC metasurface reflector.

The quasi-BIC metasurface reflector may exhibit an extremely high circular dichroism. Circular dichroism may be polarization selectivity, e.g. a reflectance for one circular polarization is zero while the other is or very close to 100% without any parasitic absorption.

Quasi-BIC resonances can possess an extremely high Q-factor, e.g. controlled by symmetry-breaking perturbations of optical nano-elements (also denoted as meta-atom) that form the quasi-BIC metasurface. The quasi-BIC metasurface can provide mode selectivity. Mode selectivity can force a laser beam of the VCSEL component to potentially operate in a single mode or at least with a minimal number of modes depending on the aperture size and emission wavelength.

As an example of wavelength selectivity, a quasi-BIC metasurface reflector having chiral quasi-BIC resonance may have a reflectance having a linewidth of ~0.02 λ/a, wherein “a” is the unit meta-atom cell width, e.g. a width of the optical nano-element. For example, this may correspond to a linewidth of about 3 nm for a laser wavelength of 650 nm assuming a width of the meta-atom of 160 nm (a=160 nm).

For example, the VCSEL component may maintain a single mode operation as long as the free spectral range between resonant modes in the VCSEL cavity is larger than the chiral quasi-BIC resonance linewidth of the quasi-BIC metasurface reflector. Thus, the chiral quasi-BIC metasurface reflector allows to force the mode inside the VCSEL cavity to be chiral, e.g. a superposition of linearly polarized modes with a proper phase delay between them, e.g. ±π/2 between x-polarization and y-polarization (for a laser beam propagating in z-direction). Thus, the chiral quasi-BIC metasurface reflector may force stimulated emission to couple to the chiral modes. The high reflectance of the quasi-BIC metasurface allows to the quasi-BIC metasurface reflector instead of a distributed Bragg reflector (DBR) in a typical VCSEL structures.

Therefore, the VCSEL component having at least one quasi-BIC metasurface reflector provides a significantly thinner VCSEL compared to VCSELs having DBR mirrors, and hence the VCSEL component has an improved vertical integrability.

The VCSEL component having at least one quasi-BIC metasurface reflector may provide a chiral laser at the chip level providing an extremely compact source of chiral light. The quasi-BIC metasurface reflector in place of a multilayer DBR stack may provide a thinner VCSEL than a typical VCSEL with DBR mirror.

The polarization selectivity may be an inherent characteristic of the metasurfaces geometry which may not be impacted by temperature effects or electrical jitters. Thus, the VCSEL component having at least one quasi-BIC metasurface reflector may provide a stable polarization state. For example, once the VCSEL component has been designed to lase for right-handed circular polarization, the VCSEL component will only lase for right-handed circular polarization.

The VCSEL component having at least one quasi-BIC metasurface reflector may provide inherent single mode emission. For example, the quasi-BIC metasurface may exhibit a very narrow linewidth and thus the VCSEL component may allow to selectively filter a particular transverse mode of the VCSEL due to its narrow linewidth. This way, single mode emission of VCSEL components of relatively larger aperture sizes can be provided as long as the free spectral range between cavity modes are larger than the linewidth of the chiral quasi-BIC resonance.

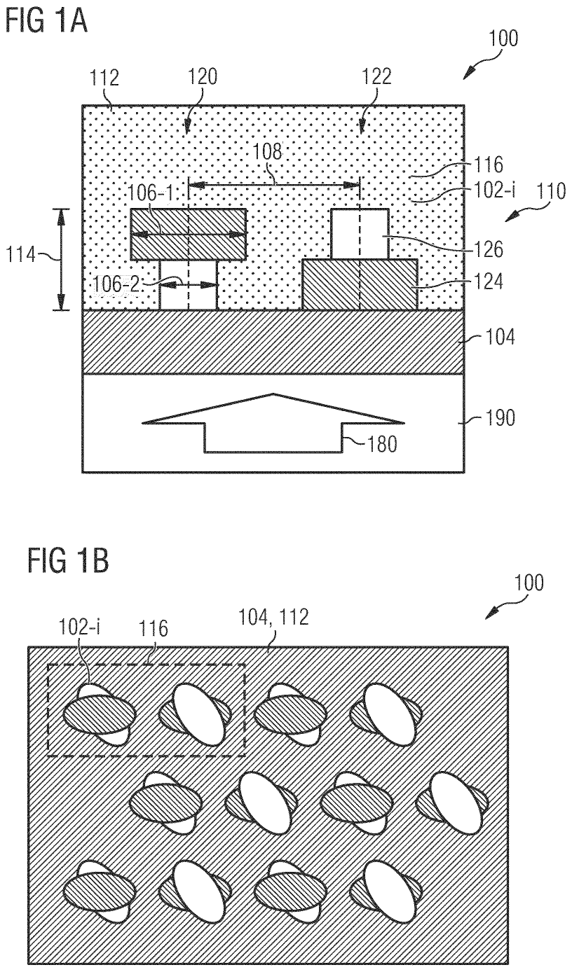

FIG. 1A shows a schematic cross-sectional side view of a VCSEL component. FIG. 1B shows a schematic cross-sectional top view of a VCSEL component. The vertical cavity surface emitting laser, VCSEL, component 100 may include a light emitting structure 190 configured to emit a light 180 of a frequency and at least one mirror structure 110 on or above the light emitting structure 190. The light emitting structure 190 and the mirror structure 110 may be integrated on a shared semiconductor substrate (not illustrated).

The mirror structure 110 includes a plurality of optical nano-elements 102-i (with i being an integer). An arrangement of optically coupled optical nano-elements 102-i, e.g. pillars, has a resonance frequency (or resonance wavelength) in the pillar library depending among others on the size 106-1, 106-2 (e.g. diameter) and pitch 108 of the pillars forming the arrangement. Optically coupled may be understood that the optical nano-elements 102-i may cause an optical resonance in the optical spectrum. Thus, the arrangement of optically coupled optical nano-elements 102-i may reflect light 180 of the light source 190 corresponding in its frequency to the resonance frequency of the arrangement of optically coupled optical nano-elements 102-i. Additionally, the optical nano-element 102-i may be formed that their structure defines a reflectivity depending on the chirality of the light 180, as described in detail below. This way, the VCSEL component 100 can emit light of a defined chirality corresponding to a high reflectivity of the optical nano-elements 102-i. Note, the resonance may not be caused by the geometry of a single pillar, but it is a collective phenomenon of optically coupled optical nano-elements 102-i in the arrangement of optically coupled optical nano-elements 102-i.

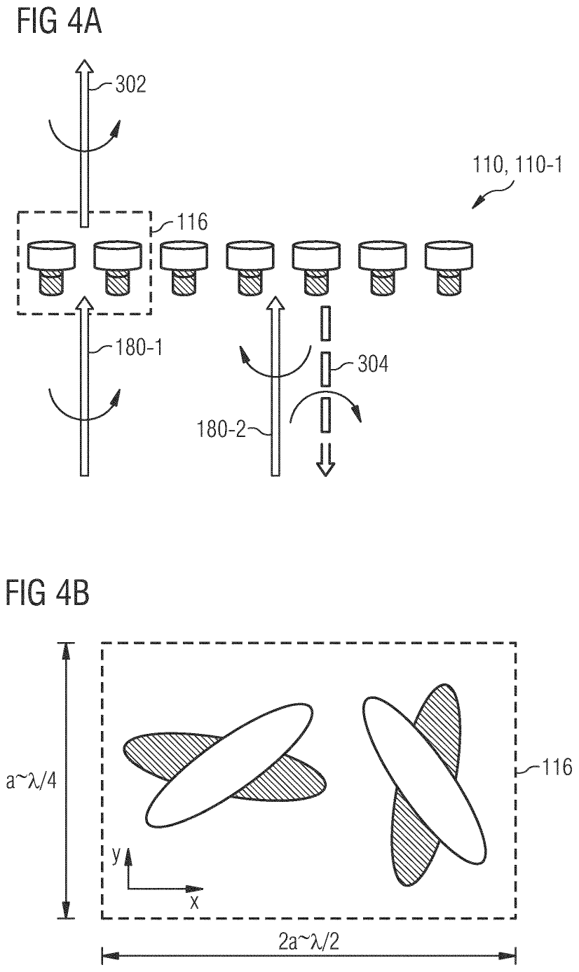

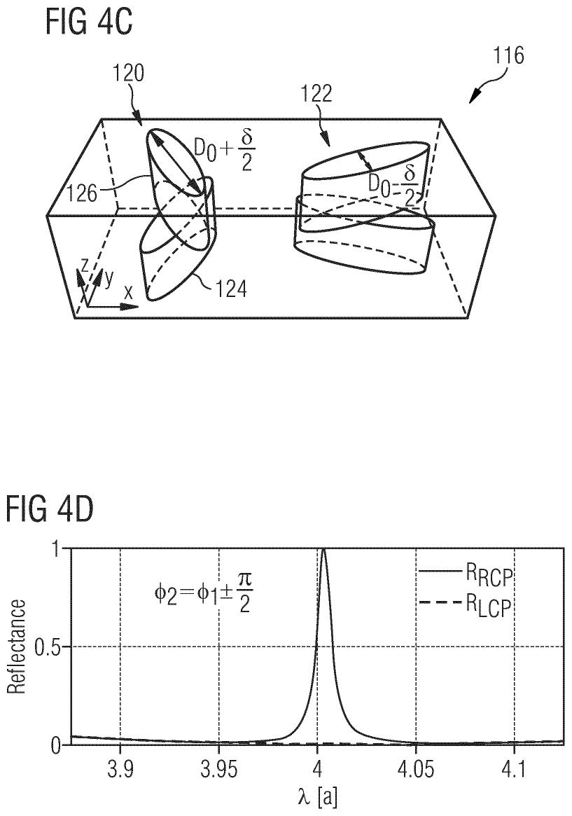

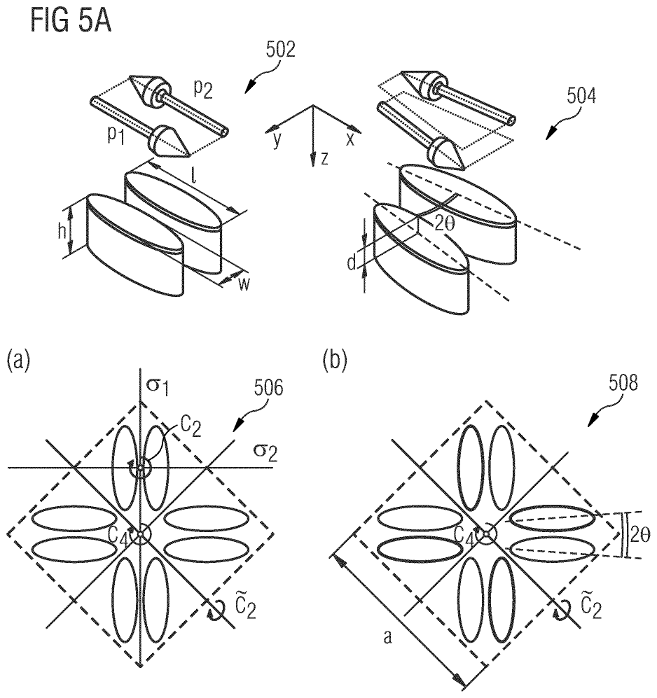

In other words, the vertical cavity surface emitting laser, VCSEL, component 100, may include a light emitting structure 190 configured to emit a light 180 of a frequency, and at least one mirror structure 110 on or above the light emitting structure 190. The mirror structure 110 may include a plurality of optical nano-elements 102-i. The optical nano-elements 102-i may be configured to include a first reflectivity for light 180 of the frequency having a first chirality and a second reflectivity for light 180 of the frequency having a second chirality (see also FIG. 4A and FIG. 4D). The second chirality may be opposing to the first chirality. The first reflectivity may be larger than the second reflectivity (see also FIG. 4D). The plurality of optical nano-elements 102-i may be configured as metastructure for the light 180 emitted from the VCSEL component 100. For example, the plurality of optical nano-elements 102-i of at least a subset of the plurality of optical nano-elements 102-i may be optically coupled in a lateral direction. The plurality of optical nano-elements 102-i may be configured to include an optical resonance frequency corresponding to the frequency of the light 180 emitted by the light emitting structure 190. For example, the plurality of optical nano-elements 102-i may be configured to include an optical resonance frequency corresponding to the frequency of the light 180 emitted by the light emitting structure 190 having the first chirality.

The plurality of optical nano-elements 102-i may include a plurality of optical nano-element pairs 116, wherein each optical nano-element pair 116 may include a first optical nano-element 120 and a second optical nano-element 122. The first optical nano-element 120 differs in at least one characteristic from the second optical nano-element 122. The characteristic may be any one of a shape, a wall angle, a pitch 108, an orientation, a width 106-1, 106-2, a height 114, an orientation of the subportions 124, 126, etc. For example, each of the optical nano-elements 102-i, 120, 122 may include an elongated shape or ellipsoidal shape. Each of the optical nano-elements 102-i, 120, 122 may include a first elongated subportion 124 and a second elongated subportion 126. The first elongated subportion 124 and the second elongated subportion 126 may be arranged in different directions to one another, e.g. for each of the first optical nano-element 120 and the second optical nano-element 122.

Note, the optical nano-element pair 116, e.g. as a unit cell, is illustrated as having two optical nano-elements per unit cells. However, the nano-element pair 116 (unit cell) may have more than two optical nano-element, e.g. arranged in a line, a zick-zack pattern, a triangle, a meander or multi-edge pattern.

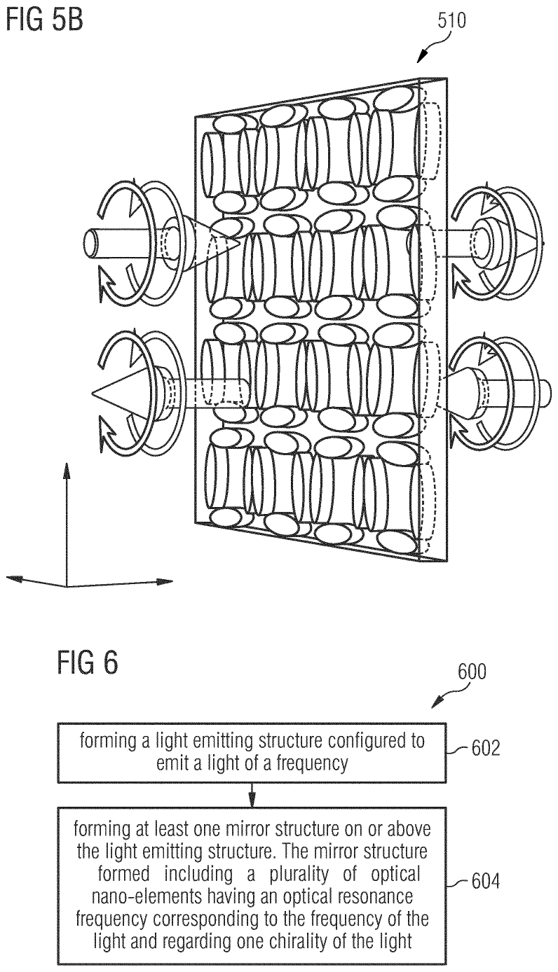

Further note, that the optical nano-elements 120, 122 are illustrated as having two optical subportion per optical nano-element. However, the nano-elements may have only one (e.g. in case of adjacently arranged optical nano-elements (see FIG. 5A and FIG. 5B) or more than two stacked subportions per optical nano-element, e.g. arranged as a stack. The subportions of an optical nano-element may differ in at least one characteristic from one another, e.g. an orientation, a shape (e.g. elongation, non-circularity), a material composition, a pitch, a rotation angle, a tilt angle, a wall angle, etc.

As an example, the first elongated subportion 124 may be arranged on or above the second elongated subportion 126. In other words, the first elongated subportion 124 and the second elongated subportion 126 may be stacked on one another. Alternatively, the first elongated subportion 124 and the second elongated subportion 126 may be arranged in a shared plane adjacent to one another (see FIG. 5A). The first optical nano-element 120 and the second optical nano-element 122 may be tilted to one another, e.g. see FIG. 5A. Alternatively, or in addition, the first optical nano-element 120 and the second optical nano-element 122 may be rotated to one another, e.g. see FIG. 5A. The first optical nano-element 120 and the second optical nano-element 122 may be arranged in an angle to one another, e.g. see FIG. 5A. The first optical nano-element 120 may be elongated in a first direction and the second optical nano-element 122 may be elongated in a second direction orthogonal to the first direction (see FIGS. 4b, 4C, 5B). The first optical nano-element 120 and the second optical nano-element 122 may be arranged in a regular pattern (see FIG. 1B). At least a subset of the optical nano-element pairs 116 may be arranged in a regular pattern (see FIG. 1B). Note, that the optical nano-elements illustrated in FIG. 1A and FIG. 1B only illustrate the principle. Details of the optical nano-elements regarding the chiral-dependent reflectivity are described in OVERVIG and GORKUNOV for example.

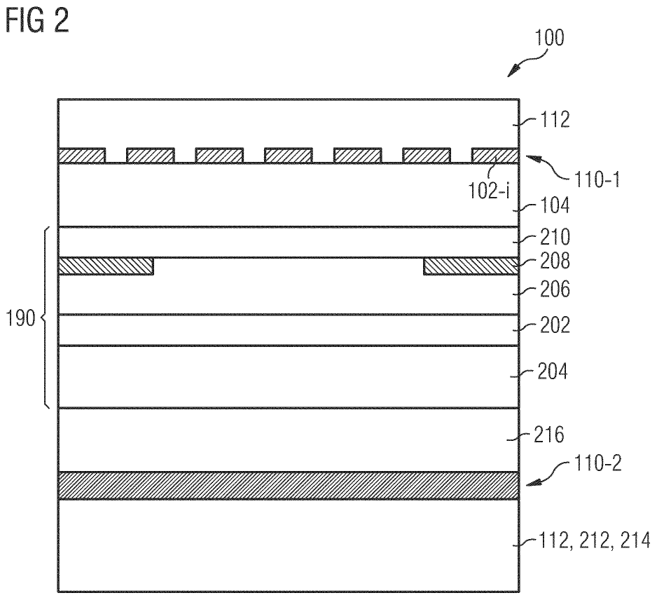

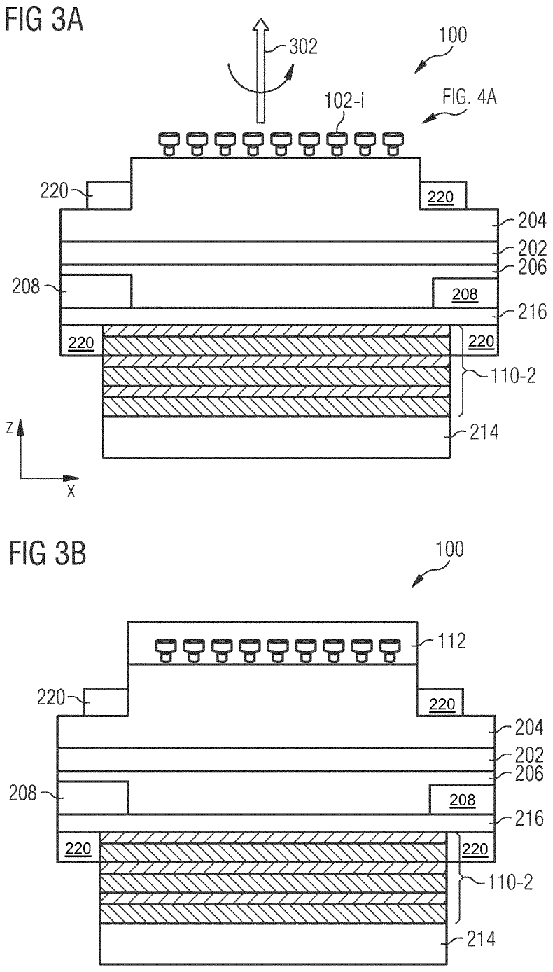

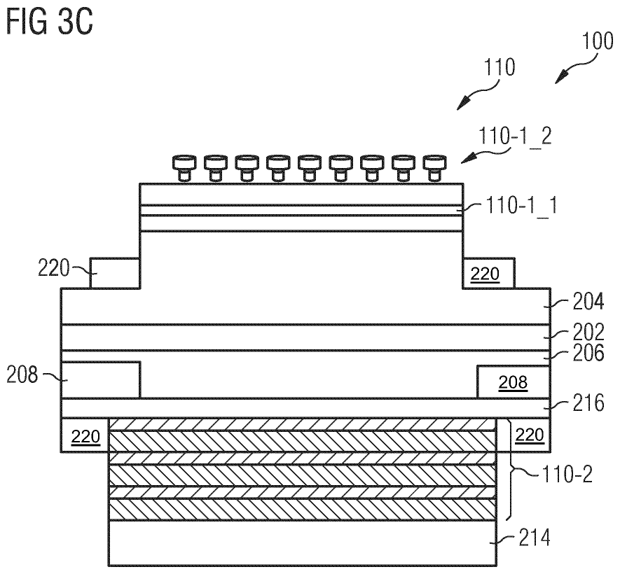

As further illustrated in FIG. 1A-FIG. 2, a dielectric layer 104 may be formed between the light emitting structure 190 and the mirror structure 110. The dielectric layer 104 may be any one of an encapsulation layer, a DBR, a planarization layer, an optical buffer layer, etc. The plurality of optical nano-elements 102-i may be formed directly on a surface of the dielectric layer 104. As further illustrated in FIG. 3C, one or more dielectric layer(s) 110-1_1 (forming the DBR) may be formed on or above the light emitting structure 190. The plurality of optical nano-elements 102-i may be formed directly on a surface of at least one dielectric layer 104. For example, the one or more dielectric layer(s) may be part of a DBR 110-1_1. In other words, the mirror structure 110, 110-1 may include a distributed Bragg reflector, DBR, 110-1_1. The DBR 110-1_1 may be arranged between the light emitting structure 190 and the plurality of optical nano-elements 110-1_2, as illustrated in FIG. 3C.

In various embodiments, the optical nano-elements of an optical nano-element pair may differ in any one of a structure of the optical nano-elements 102-i and an arrangement of the arrangement positions of the optical nano-elements 102-i. However, optical nano-elements may be configured such that the plurality of optical nano-elements 102-i may include an optical resonance frequency corresponding to the frequency of the light 180 emitted by the light emitting structure and to at least one chirality of the light emitted by the light emitting structure. The optical resonance frequency of the plurality of optical nano-elements 102-i corresponds to any one of a lateral extension optical nano-elements 102-i, a tapering angle (e.g. wall angle) of the optical nano-elements 102-i, a lateral distance of adjacent optical nano-elements 102-i (e.g. center-to-center, or sidewall-to-sidewall; also denoted as pitch), a height of optical nano-elements 102-i, a shape of the optical nano-elements 102-i (e.g. any one of an elongated cylindrical shape, an ellipsoidal cross sectional shape, a linear cross sectional shape), a material (e.g. refractive index) of the plurality of optical nano-elements 102-i, an arrangement of the plurality of optical nano-elements 102-i, an incident angle of the light on the plurality of optical nano-elements 102-i, or any combination thereof.

The optical nano-elements 102-i of an optical nano-element pair may be spaced apart by a distance 108 in a range from about 100 nm to about 1000 nm, e.g. in a range from about 200 nm to about 600 nm, e.g. in a from about 250 nm to about 500 nm.

The optical nano-elements 102-i of an optical nano-element pair may have a height 114 in a range from about 10 nm to about 10000 nm, e.g. in a range from about 200 nm to about 1600 nm, e.g. in a from about 450 nm to about 800 nm.

The optical nano-elements 102-i of an optical nano-element pair may have a lateral extension in a range from about 10 nm to about 1000 nm, e.g. in a range from about 50 nm to about 700 nm, e.g. in a from about 100 nm to about 350 nm.

The optical nano-elements 102-i of an optical nano-element pair may have a tapering angle “a” in a range from about 80° to about 90°, e.g. in a from about 82° to about 90°, e.g. in a from about 85° to about 88°.

The plurality of optical nano-elements 102-i may be configured as metastructure for the light emitted from the VCSEL component 100. For example, the plurality of optical nano-elements 102-i of at least a subset of the plurality of optical nano-elements 102-i may be optically coupled in a lateral direction. The plurality of the nano-elements may be arranged in a regular pattern. The arrangement of the arrangement positions of the optical nano-elements may correspond to a regular grid of positions, wherein each arrangement position corresponds to a grid position. The regular grid may be any one of a monoclinic grid, an orthorhombic grid, a tetragonal grid and a hexagonal grid.

The mirror structure 110 having the plurality of optical nano-elements 102-i can have a high reflectivity and low transmission for light having a frequency corresponding to the optical resonance frequency of the plurality of optical nano-elements 102-i. This way, the mirror structure 110, and hence the VCSEL component 100, may be free of a Distributed Bragg Reflecting, DBR, mirror as mirror structure.

FIG. 2 shows a schematic cross-sectional side view of a VCSEL component. The light emitting structure 190 may include a p-contact semiconductor layer 206, an n-contact semiconductor layer 204 and an active region 202 (e.g. a Multi-Quantum-Well, MQW) arranged between the p-contact semiconductor layer 206 and the n-contact semiconductor layer 204.

A transparent contact layer 210 (optional, e.g. a transparent conductive oxide, e.g. indium tin oxide, ITO)) may be arranged on the p-contact semiconductor layer 206. The contact layer 210 may be configured for electrical connecting the p-contact semiconductor layer 206 with an external voltage source.

An aperture 208, e.g. formed by an opaque layer, may define an optical field of the VCSEL component. The aperture 208 may be any one of an optical confinement and an electrical confinement in the VCSEL component.

In addition, another transparent contact layer 216 (optional, e.g. a transparent conductive oxide, e.g. indium tin oxide, ITO)) may be arranged on the n-contact semiconductor layer 204. The further contact layer 216 may be configured for electrical connecting the n-contact semiconductor layer 204 with an external voltage source. A contact structure 220 may be used for electrical contacting the semiconductor layers 202, 204, 206 of the VCSEL component, e.g. see FIG. 3A-3C.

The light emitting structure 190 may have a first side and a second side opposite to the first side. The mirror structure 110 may be a first mirror structure 110-1 arranged at the first side of the light emitting structure 190, and the VCSEL component 100 further may include a second mirror structure 110-2 arranged at the second side of the light emitting structure 190, as illustrated in FIG. 2-FIG. 3C. The second mirror structure 110-2 may include a DBR. The second mirror structure 110-1 further may include a metal reflector 214 on the DBR. In other words, the light emitting structure 190 may be arranged on a first side of the DBR and the metal reflector 214 may be arranged on a second side of the DBR. The second side of the DRB may be opposite to the first mirror of the DBR.

The metal reflector 214 may also form or act as an encapsulation layer 214.

Alternatively, or in addition, the second mirror structure 110-2 (e.g. optionally including the metal reflector 214) may be formed on a substrate 212.

The VCSEL component 100 may include an optical cavity, e.g. formed by the layers of the light emitting structure 190, the dielectric layer(s) 104, the mirror structure(s) 110-1, 110-2, and the (optional) embedding layer(s) 112. The optical cavity, e.g. by design of the layer thickness, e.g. of the dielectric layer(s) 104, may be configured to support at least one node of a standing wave of the light 180 emitted from the light emitting structure 190. The mirror structure 110 may be arranged in the optical cavity at about a position of the optical node in the optical cavity respectively.

The p-contact semiconductor layer 206 may be formed of p-GaN and the n-contact semiconductor layer 204 may be formed of n-GaN having a refractive index of about 2.5 respectively.

FIG. 3a-3c Show Schematic Cross-sectional Side Views of Vcsel Components.

FIG. 3A is a schematic cross-sectional view of a chiral VCSEL component. Note, FIG. 3A illustrates only the central part of the VCSEL component where the optical mode resides.

FIG. 3B and FIG. 3C illustrate schematic cross-sections of alternatives of chiral VCSEL components 100. For example, in FIG. 3B, the VCSEL component 100 includes an encapsulation layer 112 as protective layer. In other words, an encapsulation layer 112 may be arranged on or above the plurality of optical nano-elements 102-i. The encapsulation layer 112 may be further formed in the interspace between adjacent optical nano-elements 102-i. The encapsulation layer 112 can protect the plurality of optical nano-elements 102-i from physical damage and as dust interaction protection. Alternatively, or in addition, the encapsulation layer 112 can provide a surface having a lower roughness (e.g. root mean square roughness (RMS)) than the surface of the dielectric layer 104 having the plurality of optical nano-elements 102-i. However, the encapsulation layer 112 can be optional depending on the application of the VCSEL component 100. Thus, a surface of the mirror structure 110 may include or correspond to an emission surface of the VCSEL component 100 to emit light emitted in the light emitting structure 190 to an environment of the VCSEL component 100.

In FIG. 3C, the (first) mirror structure 110-1 may include a multilayer DBR stack 110-1_1, e.g. in case the reflectance response of the plurality of optical nano-elements 110-1_2 needs to be increased (application-specific).

FIG. 4A-4D show illustrations of details of a chiral mirror structure of a VCSEL component. FIG. 4A illustrates a perspective view of the optical nano-element pairs 116 of a mirror structure 110, 110-1 of the VCSEL component and the light 180-1, 180-2 emitted from the light emitting structure. Note, light 302 having left chirality may be transmitted by the mirror structure 110, 110-1 while light 304 having right chirality is reflected by the mirror structure 110, 110-1.

FIG. 4B illustrates a top view of an exemplary optical nano-element pair 116 and FIG. 4C illustrates a schematic perspective of the optical nano-element pair 116. Details of the structure are described in OVERVIG and GORKUNOV.

Illustratively, the quasi-BIC metasurface of the mirror structure 110, 110-1 (e.g. see FIG. 1A) may act as a reflector of the VCSEL component and may force the selection of chiral modes of the light received from the light emitting structure (see e.g. FIG. 4A). Alternatively, or in addition, the metasurface structure of the mirror structure 110, 110-1 may ensure wavelength selectivity through its high Q-factor/narrow linewidth chiral quasi-BIC resonant optical response.

The optical nano-elements 102-i forming the metasurface can be made purely by dielectric materials, e.g. any one of TiO2, NbOx, SiN, SiO2, Si (e.g. for infrared light). The material of the optical nano-elements 102-i may be selected with no to minimal absorption, e.g. less than 2% of incoming light, of the emitted light.

Illustratively, a first optical nano-element 120 (also denoted as first meta-atom) and a second optical nano-element 122 (also denoted as second meta-atom) may form an optical nano-element pair 116 (also denoted as supercell). The quasi-BIC metasurface may include a plurality of optical nano-element pairs 116. Each of the first optical nano-element 120 and the second optical nano-element 122 may include a first elliptic cylinder (e.g. first subportion) and a second elliptic cylinder (e.g. second subportion) stacked above each other or superimposed with respect to one another. The first elliptic cylinder and the second elliptic cylinder may be rotated with respect to one another. The first elliptic cylinder and the second elliptic cylinder may be tilted with respect to one another.

FIG. 4D illustrates the reflectance diagram of an optical nano-element pair for right chiral polarization and left chiral polarization according to OVERVIG as a function of wavelength of the light emitted from the light emitting structure (2) and width “a” of an optical nano-element. As illustrated, the optical nano-element pair shows a high reflectance R for right chiral polarized light. Nearly 100% right-handed circular polarization (RCP) is reflected at the resonant wavelength and while the left-handed circular polarization (LCP) is fully transmitted.

FIG. 5A-5B show illustrations of details of a chiral metasurface structure of a VCSEL component. FIG. 5A and FIG. 5B illustrate another arrangement of the optical nano-elements of an optical nano-element pair as described in detail in GORKUNOV. Here, the optical nano-elements of an optical nano-element pair can be arranged in a shared plane in parallel 502 or tilted to one another. Note that, in FIG. 5A, the top illustrations 502, 504 show perspective views of an optical nano-element pair 116, and the lower illustration 506, 508 show corresponding top views of the optical nano-elements of the above optical nano-element pair. FIG. 5B illustrates the chirality of light (arrows) passing through a metasurface structure 510 based on GORKUNOV.

FIG. 6 illustrates a flow diagram of a method 600 to manufacture a vertical cavity surface emitting laser, VCSEL, component 100. The method 600 may include forming 602 a light emitting structure 190 configured to emit a light 180 of a frequency, and forming 604 at least one mirror structure 110 on or above the light emitting structure 190. The mirror structure 110 may be formed including a plurality of optical nano-elements 102-i. The optical nano-elements 102-i may be configured to include a first reflectivity for light 180 of the frequency having a first chirality and a second reflectivity for light 180 of the frequency having a second chirality. The second chirality may be opposing to the first chirality. The first reflectivity may be larger than the second reflectivity. The plurality of optical nano-elements may be configured to include an optical resonance frequency corresponding to the frequency of the light 180 emitted by the light emitting structure 190 having the first chirality.

The method may further include any feature as described for the device above.

In the following some examples are described, which relate to what is described herein and shown in the figures.

Example 1 is a vertical cavity surface emitting laser, VCSEL, component, including a light emitting structure configured to emit a light of a frequency, and at least one mirror structure on or above the light emitting structure. The mirror structure includes a plurality of optical nano-elements. The optical nano-elements are configured to include a first reflectivity for light of the frequency having a first chirality and a second reflectivity for light of the frequency having a second chirality. The second chirality is opposing to the first chirality. The first reflectivity is larger than the second reflectivity.

In Example 2, the subject matter of Example 1 can optionally include that the plurality of optical nano-elements is configured to include an optical resonance frequency corresponding to the frequency of the light emitted by the light emitting structure having the first chirality.

In Example 3, the subject matter of Example 1 or 2 can optionally include that the plurality of optical nano-elements is configured to include an optical resonance frequency corresponding to the frequency of the light emitted by the light emitting structure.

In Example 4, the subject matter of any one of Examples 1 to 3 can optionally include that the plurality of optical nano-elements includes a plurality of optical nano-element pairs, wherein each optical nano-element pair includes a first optical nano-element and a second optical nano-element. The first optical nano-element differs in at least one characteristic from the second optical nano-element.

In Example 5, the subject matter any one of Examples 1 to 4 can optionally include that each of the optical nano-elements includes an elongated shape or ellipsoidal shape.

In Example 6, the subject matter of any one of Examples 1 to 5 can optionally include that each of the optical nano-elements includes a first elongated subportion and a second elongated subportion. The first elongated subportion and the second elongated subportion are arranged in different directions to one another.

In Example 7, the subject matter of Example 6 can optionally include that the first elongated subportion is arranged on or above the second elongated subportion.

In Example 8, the subject matter of Example 6 or 7 can optionally include that the first elongated subportion and the second elongated subportion are stacked on one another.

In Example 9, the subject matter of Example 6 can optionally include that the first elongated subportion and the second elongated subportion are arranged in a shared plane adjacent to one another.

In Example 10, the subject matter of any one of Examples 4 to 9 can optionally include that the first optical nano-element and the second optical nano-element are tilted to one another.

In Example 11, the subject matter of any one of Examples 4 to 10 can optionally include that the first optical nano-element and the second optical nano-element are rotated to one another.

In Example 12, the subject matter of any one of Examples 1 to 11 can optionally include that each of the optical nano-elements includes an elongated shape or ellipsoidal shape. The first optical nano-element and the second optical nano-element are arranged in an angle to one another.

In Example 13, the subject matter of any one of Examples 4 to 12 can optionally include that the first optical nano-element is elongated in a first direction and the second optical nano-element is elongated in a second direction orthogonal to the first direction.

In Example 14, the subject matter of any one of Examples 4 to 13 can optionally include that the first optical nano-element and the second optical nano-element are arranged in a regular pattern.

In Example 15, the subject matter of any one of Examples 4 to 14 can optionally include that at least a subset of the optical nano-element pairs are arranged in a regular pattern.

In Example 16, the subject matter of any one of Examples 1 to 15 can optionally further include one or more dielectric layer(s) formed on or above the light emitting structure. The plurality of optical nano-elements is formed directly on a surface of at least one dielectric layer.

In Example 17, the subject matter of any one of Examples 1 to 16 can optionally include that the mirror structure includes a distributed Bragg reflector, DBR. The DBR is arranged between light emitting structure and the plurality of optical nano-elements.

In Example 18, the subject matter of any one of Examples 1 to 17 can optionally include that the light emitting structure and the mirror structure are integrated on a shared semiconductor substrate.

In Example 19, the subject matter of any one of Examples 1 to 18 can optionally include that the plurality of optical nano-elements are configured as metastructure for the light emitted from the VCSEL component.

In Example 20, the subject matter of any one of Examples 1 to 19 can optionally include that the plurality of optical nano-elements of at least a subset of the plurality of optical nano-elements are optically coupled in a lateral direction.

In Example 21, the subject matter of any one of Examples 1 to 20 can optionally include that the light emitting structure includes a p-contact semiconductor layer, an n-contact semiconductor layer and an active region arranged between the p-contact semiconductor layer and the n-contact semiconductor layer.

In Example 22, the subject matter of any one of Examples 1 to 21 can optionally include that the light emitting structure having a first side and a second side opposite to the first side. The mirror structure is a first mirror structure arranged at the first side of the light emitting structure, and the VCSEL component further includes a second mirror structure arranged at the second side of the light emitting structure.

In Example 23, the subject matter of Example 22 can optionally include that the second mirror structure includes a DBR.

In Example 24, the subject matter of Example 23 can optionally include that the second mirror structure further includes a metal reflector on the DBR. The light emitting structure is arranged on a first side of the DBR and the metal reflector is arranged on a second side of the DBR. The second side of the DRB is opposite to the first mirror of the DBR.

In Example 25, the subject matter of any one of Examples 1 to 24 can optionally further include an encapsulation layer on or above the plurality of optical nano-elements.

In Example 26, the subject matter of Example 25 can optionally include that the encapsulation layer is further formed in the interspace between adjacent optical nano-elements.

Example 27 is a method to manufacture a vertical cavity surface emitting laser, VCSEL, component. The method including forming a light emitting structure configured to emit a light of a frequency, and forming at least one mirror structure on or above the light emitting structure. The mirror structure is formed including a plurality of optical nano-elements. The optical nano-elements are configured to include a first reflectivity for light of the frequency having a first chirality and a second reflectivity for light of the frequency having a second chirality. The second chirality is opposing to the first chirality. The first reflectivity is larger than the second reflectivity.

In Example 28, the subject matter of Example 27 can optionally include that the plurality of optical nano-elements is configured to include an optical resonance frequency corresponding to the frequency of the light emitted by the light emitting structure having the first chirality.

Example 29 is a vertical cavity surface emitting laser, VCSEL, component, including: a light emitting structure configured to emit a light of a frequency, and at least one mirror structure on or above the light emitting structure, wherein the mirror structure includes a plurality of optical nano-elements, wherein an interspace is formed between adjacent optical nano-elements, wherein the optical nano-elements are configured to include a first reflectivity for light of the frequency having a first chirality and a second reflectivity for light of the frequency having a second chirality, wherein the second chirality is opposing to the first chirality, and wherein the first reflectivity is larger than the second reflectivity, and an encapsulation layer formed at least in the interspace between the plurality of optical nano-elements.

In Example 30, the subject matter of Example 29 can optionally include that the plurality of optical nano-elements includes a plurality of optical nano-element pairs, wherein each optical nano-element pair includes a first optical nano-element and a second optical nano-element, wherein the first optical nano-element differs in at least one characteristic from the second optical nano-element.

In Example 31, the subject matter of Example 30 can optionally include that wherein each of the optical nano-elements includes an elongated shape or ellipsoidal shape.

In Example 32, the subject matter of any one of Examples 29 to 31 can optionally include that each of the optical nano-elements includes a first elongated subportion and a second elongated subportion, wherein the first elongated subportion and the second elongated subportion are arranged in different directions to one another.

In Example 33, the subject matter of Example 32 can optionally include that the first elongated subportion is arranged on or above the second elongated subportion.

In Example 34, the subject matter of Example 32 can optionally include that wherein the first elongated subportion and the second elongated subportion are arranged in a shared plane adjacent to one another.

Example 35 is a vertical cavity surface emitting laser, VCSEL, component, including: a light emitting structure configured to emit a light of a frequency, and at least one mirror structure on or above the light emitting structure, wherein the mirror structure includes a plurality of optical nano-elements, wherein the optical nano-elements are configured to include a first reflectivity for light of the frequency having a first chirality and a second reflectivity for light of the frequency having a second chirality, wherein the second chirality is opposing to the first chirality, and wherein the first reflectivity is larger than the second reflectivity, and wherein the plurality of optical nano-elements includes a plurality of optical nano-element pairs, wherein each optical nano-element pair includes a first optical nano-element and a second optical nano-element, wherein the first optical nano-element differs in at least one characteristic from the second optical nano-element; and wherein the first elongated subportion is arranged on or above the second elongated subportion.

In Example 36, the subject matter of Example 35 can optionally include an encapsulation structure formed on, above or between the plurality of optical nano-elements.

In Example 37, the subject matter of any one of Examples 29 to 35 or 36 can optionally include that the encapsulation layer laterally encapsulates the optical nano-elements.

In Example 38, the subject matter of any one of Examples 29 to 35 or 36 to 37 can optionally include that the encapsulation layer is formed as a continuous layer.

In Example 39, the subject matter of any one of Examples 29 to 35 or 36 to 38 can optionally include that the encapsulation layer is formed connecting adjacent optical nano-elements.

In Example 40, the subject matter of any one of Examples 29 to 35 or 36 to 39 can optionally include that the optical nano-elements have a first refractive index and the encapsulation layer has a second refractive index, wherein the second refractive index is lower than the first refractive index

In Example 41, the subject matter of any one of Examples 29 to 35 or 36 to 40 can optionally include that the encapsulation layer is extending over a top surface of the optical nano-elements, and wherein the encapsulation layer is further formed on the optical nano-elements.

In Example 42, the subject matter of any one of Examples 29 to 35 or 36 to 41 can optionally include that the first reflectivity is about 100% and the second reflectivity is less than 90%.

In Example 43, the subject matter of any one of Examples 29 to 35 or 36 to 42 can optionally include that each of the optical nano-elements includes an elongated shape or ellipsoidal shape, wherein the first optical nano-element and the second optical nano-element are arranged in an angle to one another.

In Example 44, the subject matter of any one of Examples 29 to 43 can optionally include that the at least one mirror structure is free of a distributed Bragg mirror, DBR.

In Example 45, the subject matter of any one of Examples 29 to 44 can optionally include that the mirror structure includes a distributed Bragg reflector, DBR, wherein the DBR is arranged between light emitting structure and the plurality of optical nano-elements.

In Example 46, the subject matter of any one of Examples 29 to 45 can optionally include that the plurality of optical nano-elements of at least a subset of the plurality of optical nano-elements are optically coupled in a lateral direction.

In Example 47, the subject matter of any one of Examples 29 to 46 can optionally include that the light emitting structure includes a p-contact semiconductor layer, an n-contact semiconductor layer and an active region arranged between the p-contact semiconductor layer and the n-contact semiconductor layer.

In Example 48, the subject matter of any one of Examples 29 to 47 can optionally include a glass cover on or above the mirror structure.

The method of Example 27 or 28 may further include any feature as described for the device above.

The word “exemplary” is used herein to mean “serving as an example, instance, or illustration.” Any example or design described herein as “exemplary” is not necessarily to be construed as preferred or advantageous over other examples or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one.

The term “connected” can be understood in the sense of a (e.g. mechanical, optical and/or electrical), e.g. direct or indirect, connection and/or interaction. For example, several elements can be connected together mechanically such that they are physically retained (e.g., a plug connected to a socket) and electrically such that they have an electrically conductive path (e.g., signal paths exist along a communicative chain).

While the above descriptions and connected figures may depict optical device components as separate elements, skilled persons will appreciate the various possibilities to combine or integrate discrete optical functions into a single element. Such may include combining two or more components from a single component. Conversely, skilled persons will recognize the possibility to separate a single element into two or more discrete elements, such as splitting a single component into two or more separate component.

It is appreciated that implementations of methods detailed herein are exemplary in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

While the disclosure has been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

### REFERENCE NUMERAL LIST

100 VCSEL
102-i, optical nano-element (e.g. pillar)
104 dielectric layer
106-1, 106-2 lateral extension of optical nano-element (e.g. diameter of pillar)
108 distance, pitch
110, 110-1, 110-2 mirror structure
112 embedding layer
116 optical nano-element pair
120, 122 optical nano-element of an optical nano-element pair
124, 126 subportion of an optical nano-element
180, 180-1, 180-2 light of light emission structure
190 light emission structure
202 active region
204 n-contact layer
206 p-contact layer
208 aperture
210 transparent contact layer
216, 210 contact layer
212 substrate
214 reflective metal layer
220 contact structure
302 emitted light
304 reflected light
R reflectivity
RCP right chiral polarization
LCP left chiral polarization
502, 504, 506, 508, 508 arrangement of optical nano-elements of an optical nano-element pair
600, 602, 604 method and method steps

1. A vertical cavity surface emitting laser, VCSEL, component, comprising:
a light emitting structure configured to emit a light of a frequency, and
at least one mirror structure on or above the light emitting structure, wherein the mirror structure comprises a plurality of optical nano-elements, wherein an interspace is formed between adjacent optical nano-elements, wherein the optical nano-elements are configured to comprise a first reflectivity for light of the frequency having a first chirality and a second reflectivity for light of the frequency having a second chirality, wherein the second chirality is opposing to the first chirality, and wherein the first reflectivity is larger than the second reflectivity, and an encapsulation layer formed at least in the interspace between the plurality of optical nano-elements.

2. The VCSEL component of claim 1,
wherein the plurality of optical nano-elements comprises a plurality of optical nano-element pairs, wherein each optical nano-element pair comprises a first optical nano-element and a second optical nano-element, wherein the first optical nano-element differs in at least one characteristic from the second optical nano-element.

3. The VCSEL component of claim 2,
wherein each of the optical nano-elements comprises an elongated shape or ellipsoidal shape.

4. The VCSEL component of claim 1,
wherein each of the optical nano-elements comprises a first elongated subportion and a second elongated subportion, wherein the first elongated subportion and the second elongated subportion are arranged in different directions to one another.

5. The VCSEL component of claim 4,
wherein the first elongated subportion is arranged on or above the second elongated subportion.

6. The VCSEL component of claim 5,
wherein the first elongated subportion and the second elongated subportion are arranged in a shared plane adjacent to one another.

7. A vertical cavity surface emitting laser, VCSEL, component, comprising:
a light emitting structure configured to emit a light of a frequency, and
at least one mirror structure on or above the light emitting structure, wherein the mirror structure comprises a plurality of optical nano-elements, wherein the optical nano-elements are configured to comprise a first reflectivity for light of the frequency having a first chirality and a second reflectivity for light of the frequency having a second chirality, wherein the second chirality is opposing to the first chirality, and wherein the first reflectivity is larger than the second reflectivity, and wherein the plurality of optical nano-elements comprises a plurality of optical nano-element pairs, wherein each optical nano-element pair comprises a first optical nano-element and a second optical nano-element, wherein the first optical nano-element differs in at least one characteristic from the second optical nano-element; and
wherein the first elongated subportion is arranged on or above the second elongated subportion.

8. The VCSEL component of claim 7,
further comprising an encapsulation structure formed on, above or between the plurality of optical nano-elements.

9. The VCSEL component of claim 1,
wherein the encapsulation layer laterally encapsulates the optical nano-elements.

10. The VCSEL component of claim 1,
wherein the encapsulation layer is formed as a continuous layer.

11. The VCSEL component of claim 1,
wherein the encapsulation layer is formed connecting adjacent optical nano-elements.

12. The VCSEL component of claim 1,
wherein the optical nano-elements have a first refractive index and the encapsulation layer has a second refractive index, wherein the second refractive index is lower than the first refractive index

13. The VCSEL component of claim 1,
wherein the encapsulation layer is extending over a top surface of the optical nano-elements, and wherein the encapsulation layer is further formed on the optical nano-elements.

14. The VCSEL component of claim 1, wherein the first reflectivity is about 100% and the second reflectivity is less than 90%.

15. The VCSEL component of claim 1, wherein each of the optical nano-elements comprises an elongated shape or ellipsoidal shape, wherein the first optical nano-element and the second optical nano-element are arranged in an angle to one another.

16. The VCSEL component of claim 1, wherein the at least one mirror structure is free of a distributed Bragg mirror, DBR.

17. The VCSEL component of claim 1, wherein the mirror structure comprises a distributed Bragg reflector, DBR, wherein the DBR is arranged between light emitting structure and the plurality of optical nano-elements.

18. The VCSEL component of claim 1, wherein the plurality of optical nano-elements of at least a subset of the plurality of optical nano-elements are optically coupled in a lateral direction.

19. The VCSEL component of claim 1, the light emitting structure comprising a p-contact semiconductor layer, an n-contact semiconductor layer and an active region arranged between the p-contact semiconductor layer and the n-contact semiconductor layer.

20. The VCSEL component of claim 1, further comprising a glass cover on or above the mirror structure.
